(19) United States
(12) Patent Application Publication
(10) Pub. No.: US 2026/0002250 A1
(43) Pub. Date: Jan. 1, 2026

(54) FILM FORMATION APPARATUS AND FILM FORMATION METHOD OF GALLIUM NITRIDE FILM

(71) Applicant: Japan Display Inc., Tokyo (JP)

(72) Inventors: Masanobu IKEDA, Tokyo (JP); Masumi NISHIMURA, Tokyo (JP)

(73) Assignee: Japan Display Inc., Tokyo (JP)

(21) Appl. No.: 19/322,805

(22) Filed: Sep. 9, 2025

Related U.S. Application Data
(63) Continuation of application No. PCT/JP2024/009771, filed on Mar. 13, 2024.

(30) Foreign Application Priority Data
Apr. 4, 2023 (JP) 2023-060689

(51) Int. Cl. C23C 14/34; C23C 14/06; C23C 14/50; C23C 14/54

(52) U.S. Cl. CPC C23C 14/3407; C23C 14/0617; C23C 14/50; C23C 14/541

(57) ABSTRACT

A film formation apparatus includes a vacuum chamber capable of evacuating an interior thereof, a substrate support portion provided in the vacuum chamber and configured to support at least one substrate, a target support portion provided in the vacuum chamber and configured to support a target containing nitrogen and gallium, a sputtering gas supply unit connected to the vacuum chamber and configured to supply a sputtering gas to the vacuum chamber, a nitrogen gas supply unit connected to the vacuum chamber and configured to supply a gas containing nitrogen to the vacuum chamber, and a sputtering power supply unit configured to apply an AC voltage to the target. The substrate support portion supports the at least one substrate such that the at least one substrate periodically passes through a region overlapping the target.

### CROSS-REFERENCE TO RELATED APPLICATIONS

This application is a Continuation of International Patent Application No. PCT/JP2024/009771, filed on Mar. 13, 2024, which claims the benefit of priority to Japanese Patent Application No. 2023-060689, filed on Apr. 4, 2023, the entire contents of which are incorporated herein by reference.

### FIELD

An embodiment of the present invention relates to a film formation apparatus for forming a gallium nitride film. Further, an embodiment of the present invention relates to a method for forming a gallium nitride film.

### BACKGROUND

In general, a gallium nitride film is formed on a sapphire substrate by Metal Organic Chemical Vapor deposition (MOCVD) or Hydride Vapor Phase Epitaxy (HVPE) at a high temperature of 800° C. to 1000° C. On the other hand, recently, a method for forming a gallium nitride film using sputtering, which can be formed at relatively low temperatures, has been developed (for example, see Japanese laid-open patent publication No. 2020-164927).

### SUMMARY

A film formation apparatus according to an embodiment of the present invention includes a vacuum chamber capable of evacuating an interior thereof, a substrate support portion provided in the vacuum chamber and configured to support at least one substrate, a target support portion provided in the vacuum chamber and configured to support a target containing nitrogen and gallium, a sputtering gas supply unit connected to the vacuum chamber and configured to supply a sputtering gas to the vacuum chamber, a nitrogen gas supply unit connected to the vacuum chamber and configured to supply a gas containing nitrogen to the vacuum chamber, and a sputtering power supply unit configured to apply an AC voltage to the target. The substrate support portion supports the at least one substrate such that the at least one substrate periodically passes through a region overlapping the target.

A film formation apparatus according to an embodiment of the present invention includes a vacuum chamber capable of evacuating an interior thereof, a substrate support portion provided in the vacuum chamber and configured to support at least one substrate, a first target support portion provided in the vacuum chamber and configured to support a first target, a second target support portion provided in the vacuum chamber and configured to support a second target, a sputtering gas supply unit connected to the vacuum chamber and configured to supply a sputtering gas to the vacuum chamber, a nitrogen gas supply unit connected to the vacuum chamber and configured to supply a gas containing nitrogen to the vacuum chamber, a first sputtering power supply unit configured to apply a first AC voltage to the first target, a second sputtering power supply unit configured to apply a second AC voltage to the second target; and a control unit configured to control the first sputtering power supply unit and the second sputtering power supply unit. Each of the first target and the second target contains nitrogen and gallium. The control unit periodically controls a first ON period during which the first AC voltage is applied to the first target and a first OFF period during which the first AC voltage is not applied to the first target, and a second ON period during which the second AC voltage is applied to the second target and a second OFF period during which the second AC voltage is not applied to the second target.

A film formation method of a gallium nitride film according to an embodiment of the present invention includes the steps of placing a substrate so as to face a target containing nitrogen and gallium in a vacuum chamber, heating the substrate, moving the substrate so that at least a portion of the substrate periodically passes through a region overlapping the target, supplying a gas containing nitrogen to the vacuum chamber, and applying an AC voltage to the target.

### BRIEF DESCRIPTION OF DRAWINGS

FIG. 1 is a schematic diagram showing a configuration of a film formation apparatus according to an embodiment of the present invention.

FIG. 2 is a schematic plan view showing a positional relationship between a substrate and a target in a film formation apparatus according to an embodiment of the present invention.

FIG. 3 is a sequence diagram of a sputtering power supply unit controlled by a control unit of a film formation apparatus according to an embodiment of the present invention.

FIG. 4 is a flowchart illustrating a method for forming a gallium nitride film using a film formation apparatus according to an embodiment of the present invention.

FIG. 5 is a schematic diagram showing a configuration of a substrate support unit of a film formation apparatus according to an embodiment of the present invention.

FIG. 6 is a schematic diagram showing a part of a configuration of a film formation apparatus according to an embodiment of the present invention.

FIG. 7 is a schematic diagram showing a part of a configuration of a film formation apparatus according to an embodiment of the present invention.

FIG. 8 is a sequence diagram of sputtering power supply units controlled by a control unit of a film formation apparatus according to an embodiment of the present invention.

FIG. 9 is a schematic diagram showing a configuration of a light emitting element according to an embodiment of the present invention.

FIG. 10 is a flowchart showing a method for fabricating a light emitting device according to an embodiment of the present invention.

FIG. 11 is a schematic diagram showing a configuration of a semiconductor element according to an embodiment of the present invention.

FIG. 12 is a flowchart showing a method for manufacturing a semiconductor device according to an embodiment of the present invention.

### DESCRIPTION OF EMBODIMENTS

In recent years, the Sustainable Development Goals (SDGs) have been promoted. Since sputtering, which can form films at low temperatures, can reduce the energy required for film formation, sputtering is an attractive film formation method for achieving the SDGs. However, a gallium nitride film with sufficient quality has not been manufactured by sputtering until now.

In view of the above problems, an embodiment of the present invention can provide a film formation apparatus that can form a gallium nitride film with high quality. Further, an embodiment of the present invention can provide a method for forming a gallium nitride film with high quality.

Hereinafter, each of the embodiments of the present invention is described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification and the like, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification and the like, although the phrase “on” or “over” or “under” or “below” is used for convenience of explanation, in principle, the direction from a substrate toward a structure is referred to as “on” or “over” with reference to a substrate in which the structure is formed. Conversely, the direction from the structure to the substrate is referred to as “under” or “below.” Therefore, in the expression of “a structure over a substrate,” one surface of the structure in the direction facing the substrate is the bottom surface of the structure and the other surface is the upper surface of the structure. In addition, the expression of “a structure over a substrate” only explains the vertical relationship between the substrate and the structure, and another member may be placed between the substrate and the structure. Furthermore, the term “on” or “over” or “under” or “below” means the order of stacked layers in the structure in which a plurality of layers is stacked, and may not be related to the position in which layers overlap in a plan view.

In the present specification and the like, terms such as “first,” “second,” or “third” attached to each configuration are convenient terms used to distinguish each component, and have no further meaning unless otherwise explained.

In the present specification and the drawings, the same reference numerals may be used when multiple components are identical or similar in general, and reference numerals with a lower or upper case letter of the alphabet may be used when the multiple components are distinguished. Further, reference numerals with a hyphen and a natural number may be used when multiple portions of one component are distinguished.

In the present specification and the like, a cation and an anion may be referred to as a positive ion and a negative ion, respectively.

The following embodiments can be combined with each other as long as there is no technical contradiction.

### First Embodiment

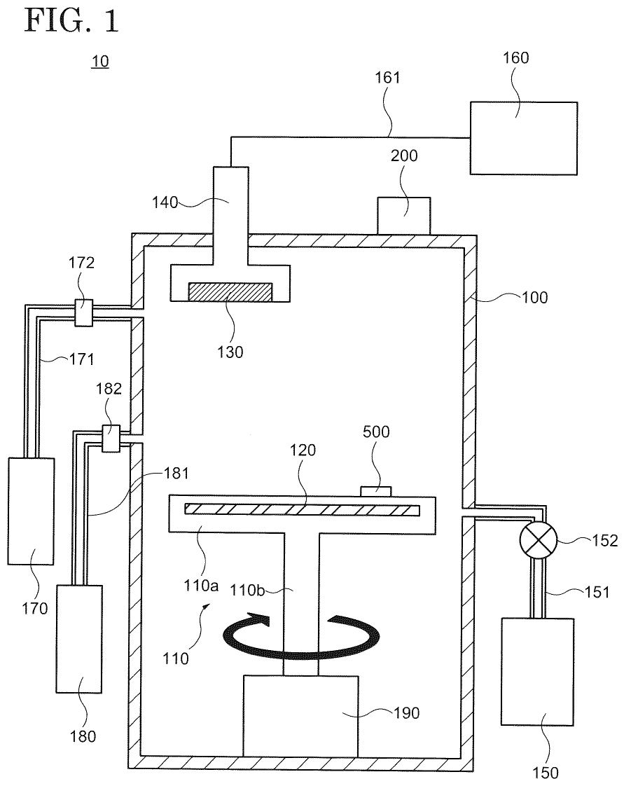

A film formation apparatus 10 and a method for forming a gallium nitride film using the film formation apparatus 10 according to an embodiment of the present invention is described with reference to FIGS. 1 to 4.

### 1. Configuration of Film Formation Apparatus 10

FIG. 1 is a schematic diagram showing a configuration of the film formation apparatus 10 according to an embodiment of the present invention.

As shown in FIG. 1, the film formation apparatus 10 includes a vacuum chamber 100, a substrate support portion 110, a heating unit 120, a target 130, a target support portion 140, a pump 150, a sputtering power source 160, a sputtering gas supply unit 170, a nitride gas supply unit 180, a rotation drive unit 190, and a control unit 200. In addition, the rotation drive unit 190 may be a portion of the substrate 110.

The substrate support portion 110, the heating unit 120, the target 130, the target support portion 140, and the rotation drive unit 190 is provided in the vacuum chamber 100. The substrate support portion 110 and the heating unit 120 are located at the bottom of the vacuum chamber 100. A substrate 500 is placed on the substrate support portion 110. Specifically, the substrate 500 is placed on a flat plate member 110a of the substrate support portion 110. Therefore, the flat plate member 110a is preferably provided with a device for fixing the placed substrate 500. The heating unit 120 is located in the flat plate member 110a of the substrate support portion 110 and can heat the substrate 500 placed on the substrate support portion 110 to a predetermined temperature. For example, the predetermined temperature is equal to or higher than 400° C. and equal to or lower than 650° C. The target 130 and the target support portion 140 are located at the top of the vacuum chamber 100. The target 130 is supported by the target support portion 140 so as to be disposed opposite to and overlap the substrate support portion 110.

In the film formation apparatus 10, a sapphire substrate, a glass substrate, or a quartz substrate can be used as the substrate 500, for example. When the film formation apparatus 10 is used, a gallium nitride film can be formed directly on a sapphire substrate even at low temperatures. However, a substrate having a buffer layer provided on a sapphire substrate can also be used as the substrate 500. Further, when the substrate 500 is a glass substrate or a quartz substrate, it is preferable that a buffer layer be provided on the glass substrate or the quartz substrate. For example, an aluminum nitride film or the like can be used as the buffer layer.

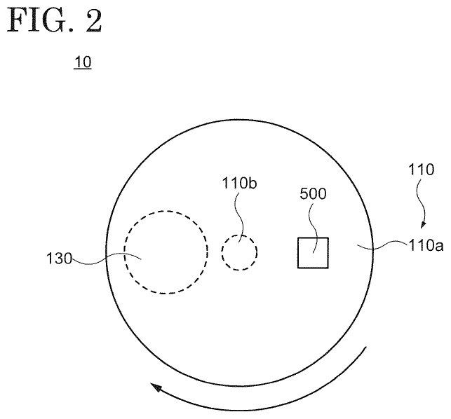

The substrate support portion 110 includes a support member 110b. One end of the support member 110b is connected to the flat plate member 110a, and the other end of the support member 110b is connected to the rotation drive unit 190. The rotation drive unit 190 can rotate the support member 110b. When the support member 110b is rotated by the rotation drive unit 190, the flat plate member 110a connected to the support member 110b also rotates in accordance with the rotation of the support member 110b. Further, the substrate 500 placed on the substrate support portion 110 also rotates in accordance with the rotation of the flat plate member 110a. In other words, the substrate support portion 110 rotatably supports the substrate 500. Hereinafter, the positional relationship between the target 130 and the substrate 500 placed on the substrate support portion 110 is described with reference to FIG. 2.

FIG. 2 is a schematic plan view showing the positional relationship between the target 130 and the substrate 500 in the film formation apparatus 10 according to an embodiment of the present invention. FIG. 2 shows the flat plate member 110a of the substrate support portion 110 and the substrate 500 placed on the substrate support portion 110. The flat plate member 110a and the target 130 which are connected to the support member 110b are shown by dotted lines in FIG. 2.

In a plan view, the support member 110b is connected to the center of the flat plate member 110a. Therefore, the substrate support portion 110 rotates around an axis passing through the center of the flat plate member 110a. The substrate 500 is placed at a position offset from the center of the flat plate member 110a. When the substrate support portion 110 rotates, the substrate 500 rotates so as to move on the circumference of a circle whose center is the flat plate member 110a. In other words, the substrate 500 revolves around the center of the flat plate member 110a.

In a plan view, the target 130 is also disposed at a position offset from the center of the flat plate member 110a. Therefore, when the substrate support portion 110 rotates, the substrate 500 rotates so as to periodically pass through a region overlapping the target 130.

In addition, although FIGS. 1 and 2 show a configuration in which the substrate support portion 110 and the heating unit 120 are provided in the bottom of the vacuum chamber 100, and the target 130 and the target support portion 140 are provided in the top of the vacuum chamber 100, the positions in which the target 130 and the target support portion 140 are provided may be reversed. Further, the rotation drive unit 190 may be provided outside the vacuum chamber 100.

The configuration of the film formation apparatus 10 will be described again with reference to FIG. 1.

The target 130 is gallium nitride containing nitrogen and gallium. It is preferable that the composition ratio of the gallium nitride in the target 130 is 0.5 to 2 of gallium to nitrogen. The nitrogen in the gallium nitride film formed on the substrate 500 is supplied from the target 130 and the nitrogen gas supply unit 180, while the gallium in the gallium nitride film is supplied only from the target 130. Therefore, it is more preferable that the composition of the gallium nitride in the target 130 contains more gallium than nitrogen.

The pump 150, the sputtering power supply unit 160, the sputtering gas supply unit 170, and the nitrogen gas supply unit 180 are provided outside the vacuum chamber 100.

The pump 150 is connected to the vacuum chamber 100 through a pipe 151. The pump 150 can exhaust gas from the vacuum chamber 100 through the pipe 151. That is, the inside of the vacuum chamber 100 can be evacuated by the pump 150 connected to the vacuum chamber 100 so as to be lower than or equal to a predetermined degree of vacuum. Although the predetermined degree of vacuum is, for example, 10-6 Pa, the degree of vacuum is not limited thereto. Further, the pressure in the vacuum chamber 100 can be kept constant by opening and closing a valve 152 connected to the pipe 151. For example, a turbo molecular pump or a cryopump can be used as the pump 150.

The sputtering power supply unit 160 is electrically connected to the target 130 through a wiring 161. The sputtering power supply unit 160 includes a high frequency power supply and a matching box. The high frequency power supply generates an AC voltage. The matching box adjusts the input/output impedance of the AC voltage. That is, the sputtering power supply unit 160 generates an AC voltage using the high frequency power supply, and the generated AC voltage is applied to the target 130 through the matching box. The frequency of the AC voltage is, for example, 13.56 MHZ. However, the configuration of the sputtering power supply unit 160 is not limited thereto. In the film formation apparatus 10 according to the present embodiment, any configuration may be used as long as an AC voltage is applied to the target 130, and a DC voltage or a pulsed DC voltage may be applied to the AC voltage as a bias voltage. In this case, the frequency of the AC voltage is, for example, 70 MHz.

The sputtering gas supply unit 170 is connected to the vacuum chamber 100 through a pipe 171. The sputtering gas supply unit 170 can supply a sputtering gas into the vacuum chamber 100 through the pipe 171. The flow rate of the sputtering gas can be adjusted by a mass flow controller 172 connected to the pipe 171. The sputtering gas supplied from the sputtering gas supply unit 170 can be argon (Ar) or krypton (Kr).

The nitrogen gas supply unit 180 is connected to the vacuum chamber 100 through a pipe 181. The nitrogen gas supply unit 180 can supply a gas containing nitrogen into the vacuum chamber 100 through the pipe 181. The flow rate of the gas containing nitrogen can be adjusted by a mass flow controller 182 connected to the pipe 181. The gas containing nitrogen supplied from the nitrogen gas supply unit 180 can be nitrogen (N₂), or a mixed gas (forming gas) of nitrogen (N₂) and hydrogen (H₂). The purity of these gases is preferably higher than or equal to 6N.

As the substrate 500 rotates in the film formation apparatus 10, the substrate 500 periodically passes through a region where the substrate 500 overlaps the target 130 (hereinafter, referred to as a “target overlapping region”) and a region where the substrate 500 does not overlap the target 130 (hereinafter, referred to as a “target non-overlapping region”). In other words, the target overlapping region and the target non-overlapping region are spatially formed within the vacuum chamber 100 in the film formation apparatus 10. Although details are described later, a step of depositing gallium on the substrate 500 (i.e., a step of supplying gallium in forming a gallium nitride film) is mainly performed in the target overlapping region when an AC voltage is applied to the target 130. Further, a step of nitriding the gallium deposited on the substrate 500 (i.e., a step of supplying nitrogen in forming a gallium nitride film) is mainly performed in the target non-overlapping region. More specifically, gallium is supplied to the substrate 500 when the substrate 500 moves so as to pass through the target overlapping region. On the other hand, nitrogen is supplied to the substrate 500 when the substrate 500 moves so as to pass through the target non-overlapping region. Thus, by performing a stepwise production reaction of gallium nitride or by intermittently supplying elements consisting of gallium nitride in the film formation apparatus 10, migration of particles containing gallium on the surface is promoted, and a gallium nitride film with high quality can be formed even at a low temperature.

In the film formation apparatus 10, sputtering can be performed while continuously applying an AC voltage to the target 130. In this case, sputtering is performed when the substrate 500 passes through the target overlapping region. However, the control unit 200 can also control the application of the AC voltage to the target 130 in the film formation apparatus 10.

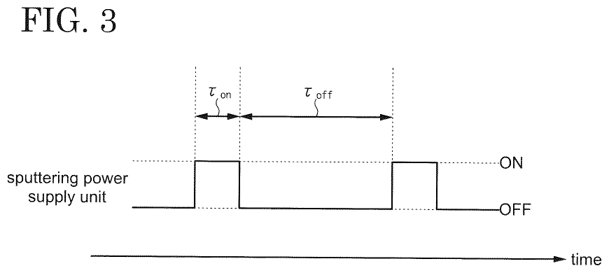

The control unit 200 can control the operation of the film formation apparatus 10 in forming the gallium nitride film. The control unit 200 is a computer that can perform arithmetic processing using data or information, and includes, for example, a central processing unit (CPU), a microprocessor (MPU), or a random access memory (RAM). Specifically, the control unit 200 executes a predetermined program to perform various controls. For example, the control unit 200 can control the pump 150, the mass flow controller 172, or the mass flow controller 182 to maintain a predetermined pressure in the vacuum chamber 100. The control unit 200 can also control the heating unit 120 to heat the substrate 500 placed on the substrate support portion 110 at a predetermined temperature. The control unit 200 can also control the rotation driver 190 to rotate the substrate support portion 110. In particular, when a gallium nitride film is formed, the control unit 200 controls the sputtering power supply unit 160. Here, control of the sputtering power supply unit 160 by the control unit 200 is described with reference to FIG. 3.

FIG. 3 is a sequence diagram of the sputtering power supply unit 160 controlled by the control unit 200 of the film formation apparatus 10 according to an embodiment of the present invention.

The control unit 200 can control the sputtering power supply unit 160 in an ON state to apply an AC voltage to the target 130. In the case where a sputtering gas is supplied into the vacuum chamber 100, when an AC voltage is applied to the target 130, plasma is generated between the substrate support portion 110 and the target 130, and sputtering is performed. In the following description, a period during which an AC voltage is applied to the target 130 is referred to as an “ON period Tₒₙ.” Further, the control unit 200 can also control the sputtering power supply unit 160 in an OFF state to stop the application of the AC voltage to the target 130. In this case, the plasma between the substrate support portion 110 and the target 130 disappears, and sputtering is not performed. In the following description, a period during which an AC voltage is not applied to the target 130 is referred to as an “OFF period T_{off}.”

As shown in FIG. 3, the control unit 200 controls the sputtering power supply unit 160 so that an ON period Tₒₙ and an OFF period T_{off} are periodically repeated. During the ON period Tₒₙ, plasma is generated between the substrate support portion 110 and the target 130, and sputtering is performed. On the other hand, during the OFF period T_{off}, plasma is not generated between the substrate support portion 110 and the target 130, and sputtering is not performed. Here, the ON period Tₒₙ is less than or equal to 25% of the total period of the ON period Tₒₙ and the OFF period T_{off}.

In the ON period Tₒₙ during which plasma is generated, atoms that inhibit the gallium nitride production reaction may be generated, or migration of particles containing gallium on the surface may be inhibited, depending on the conditions. In such cases, it is preferable to provide the OFF period T_{off} during which plasma is not generated. Further, when the OFF period T_{off} is used, it is possible to promote reactions similar to those that occur during the period during which the substrate 500 passes through the target non-overlapping region, or to promote migration of particles containing gallium on the surface. Therefore, a gallium nitride film with high quality can be formed. In the film formation apparatus 10, since the substrate 500 rotates, sputtering is not performed on the substrate 500 even during the ON period Tₒₙ unless the substrate 500 overlaps the target 130. However, the ON period Tₒₙ and the period during which the substrate 500 passes through the target overlapping region do not necessarily have to match each other. When switching between the ON period Tₒₙ and the OFF period T_{off}, the plasma is likely to become unstable, which may damage a film formed on the substrate 500. In such a case, it is preferable that the switching between the ON period Tₒₙ and the OFF period T_{off} is performed during the period during which the substrate 500 is moving through the target non-overlapping region.

### 2. Gallium Nitride Film Formation Method

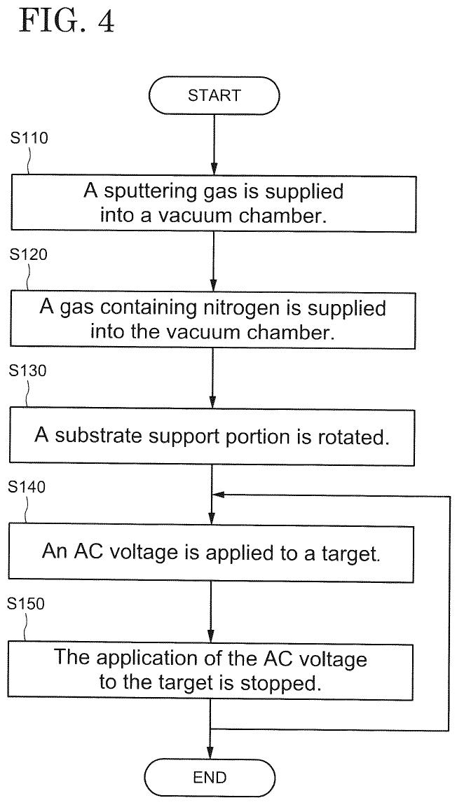

FIG. 4 is a flowchart illustrating a method for forming a gallium nitride film using the film formation apparatus 10 according to an embodiment of the present invention.

The method for forming a gallium nitride film shown in FIG. 4 starts when the substrate 500 is placed on the substrate support portion 110 and a predetermined pressure is reached in the vacuum chamber 100. The method for forming a gallium nitride film shown in FIG. 4 includes steps S110 to S150. Hereinafter, steps S110 to S150 are described in order.

In step S110, a sputtering gas is supplied into the vacuum chamber 100. The sputtering gas is supplied from the sputtering gas supply unit 170 through the pipe 171, and is introduced into the vacuum chamber 100 while the flow rate is adjusted by the mass flow controller 172.

In step S120, a gas containing nitrogen is supplied into the vacuum chamber 100. The gas containing nitrogen is supplied from the nitrogen gas supply unit 180 through the pipe 181, and introduced into the vacuum chamber 100 while the flow rate is adjusted by the mass flow controller 182. For example, when the flow rate of the sputtering gas is 10 sccm, the flow rate of the gas containing nitrogen is greater than or equal to 50 sccm and less than or equal to 200 sccm. Thus, it is preferable that the flow rate of the gas containing nitrogen is greater than or equal to 5 times and less than or equal to 20 times the flow rate of the sputtering gas.

In step S130, the substrate support portion 110 is rotated. Thus, the substrate 500 placed on the substrate support portion 110 is also rotated, and the substrate 500 periodically passes through the target overlapping region.

In step S140, an AC voltage is applied to the target 130. That is, step S140 corresponds to the ON period Tₒₙ. The AC voltage is generated by the sputtering power supply unit 160 and applied to the target 130 via a matching box. Thus, a glow discharge occurs between the substrate support portion 110 and the target 130, the sputtering gas is ionized, and plasma is generated. Specifically, plasma is generated in the target overlapping region between the target 130 and the substrate support portion 110. When ions of the sputtering gas or a gas containing nitrogen collide with the target 130 in the target overlapping region, particles such as gallium or gallium nitride are ejected from the target 130. Hereinafter, particles such as gallium or gallium nitride ejected from the target 130 may be referred to as “sputtered particles.”

In step S140, when the substrate 500 passes through the target overlapping region, sputtered particles ejected from the target 130 are deposited on the substrate 500. On the other hand, when the substrate 500 moves in the target non-overlapping region, sputtered particles are less likely to be deposited on the substrate 500. Further, when the substrate 500 moves in the target non-overlapping region, the substrate 500 is not exposed to plasma so that the film formed by the deposition of sputtered particles is less likely to be damaged.

In step S140, since the substrate 500 is rotated while maintaining the application of the AC voltage to the target 130, sputtering occurs in the target overlapping region and sputtering does not occur in the target non-overlapping region. When the gas containing nitrogen is a forming gas, the hydrogen contained in the forming gas can remove residual oxygen in the vacuum chamber 100 and reduce gallium oxide deposited as an impurity on the substrate 500.

Step S150 can be executed as needed. In step S150, the application of the AC voltage to the target 130 is stopped. That is, step S150 corresponds to the OFF period T_{off}. Since the plasma in the target overlapping region is extinguished, no sputtered particles are ejected from the target 130. Therefore, even when the substrate 500 passes through the target overlapping region, sputtered particles are unlikely to be deposited on the substrate 500.

In addition, in step S150, it is preferable to supply a gas containing nitrogen into the vacuum chamber 100. Nitrogen constituting gallium nitride can be intermittently supplied not only during the period when the substrate 500 passes through the target non-overlapping region but also during the OFF period T_{off}.

In forming a gallium nitride film using the film formation apparatus 10, either step S140 or steps S140 and S150 is repeated to form a gallium nitride film having a predetermined thickness on the substrate 500.

Here, the mechanism of forming a gallium nitride film using the film formation apparatus 10 is described. The sputtering yield S is the statistical ratio of the number of atoms that are ejected from the target when one ion, atom, or molecule collides with the target. In other words, when the sputtering yield is high, a large number of sputtered particles are ejected from the target, and sputtering is performed efficiently. The sputtering yield S is roughly expressed as in formula (1), where M1 is the mass (atomic weight or molecular weight) of the incident particle that is incident on the target, and M2 is the mass of the sputtered particle that is ejected from the target. In addition, E in formula (1) is the electric field.

$$S ∝ \frac{4 {M}_{1} {M}_{2}}{{( {M}_{1} + {M}_{2} )}^{2}} E \qquad ( 1 )$$

As can be seen from equation (1), the sputtering yield S is proportional to the coefficient 4M₁M₂/(M₁+M₂)² of the electric field E. Here, the coefficient 4M₁M₂/(M₁+M₂)₂ is calculated when the incident particle is an argon cation (Ar⁺), a nitrogen anion (N⁻), and a nitrogen molecule (N₂), and the sputtered particle is a gallium atom (Ga) and a gallium nitride (GaN), and the calculation results are shown in Table 1.

TABLE 1

| | | Incident Particle | | |
|---|---|---|---|---|
| | | Ar⁺ | N⁻ | N₂ |
| Sputtered | Ga | 0.94 | 0.55 | 0.82 |
| Particle | GaN | 0.87 | 0.49 | 0.75 |

The larger the coefficient shown in Table 1, the larger the sputtering yield S. As can be seen from Table 1, when the incident particle is Ar⁺ and N₂, the sputtering yield S is large. On the other hand, when the incident particle is N⁻, the sputtering yield S is small. This calculation result is consistent with actual sputtering. In the target overlapping region, N⁻, which is an anion, is accelerated toward the substrate 500, not toward the target 130. Therefore, N⁻ hardly contributes as an incident particle in sputtering.

An N⁻ accelerated toward the substrate 500 etches the Ga and GaN deposited on the substrate 500. Therefore, when the substrate 500 is in the plasma, Ga and GaN are deposited on the substrate 500 by the Ga⁺ and N₂, while the Ga and GaN on the substrate 500 are etched by the N⁻. Further, since not only the Ga and GaN are etched, but also the film deposited on the substrate 500 is damaged, the crystalline quality of the film is reduced.

Therefore, in step S140, the substrate 500 is rotated to spatially form the target overlapping region where sputtering is performed and the target non-overlapping region where sputtering is not performed within the vacuum chamber 100 in the film formation apparatus 10 according to the present embodiment. In the target non-overlapping region, etching by N⁻ is not performed. Further, Ga, which is a Group 13 element, is likely to migrate on the surface of the substrate 500. Accordingly, in the target non-overlapping region, since Ga migration on the surface of the substrate 500 is promoted, and a gas containing nitrogen is supplied into the vacuum chamber 100, Ga on the surface of the substrate 500 reacts with nitrogen or a nitrogen radical with a long lifetime in the supplied gas to form a gallium nitride film on the substrate 500. Since etching by N⁻ is not performed and damage to the film formed on the substrate 500 can be reduced, the gallium nitride film formed using the film formation apparatus 10 is a high-quality film.

Further, in step S150, the sputtering power supply unit 160 is controlled to stop applying an AC voltage to the target 130 in the film formation apparatus 10 according to the present embodiment. Thus, the plasma in the target overlapping region disappears. In this case, etching by N⁻ is also not performed. Therefore, during the OFF period T_{off}, since a migration of Ga on the surface of the substrate 500 is promoted, and a gas containing nitrogen is supplied into the vacuum chamber 100, Ga on the surface of the substrate 500 reacts with nitrogen or a nitrogen radical with a long lifetime in the supplied gas, thereby forming a gallium nitride film on the substrate 500.

However, when an AC voltage is applied to the target 130, adjusting the impedance to generate a stable plasma requires a certain amount of time, and switching between the ON period Tₒₙ and the OFF period T_{off} in a short period of time is often difficult. Further, switching between the ON period Tₒₙ and the OFF period T_{off} in a short period of time places a large load on the sputtering power supply unit 160, which may reduce the durability of the sputtering power supply unit 160. Therefore, in the present embodiment, the substrate 500 is controlled so that it periodically passes through the target overlapping region while the substrate 500 is rotated. Even during the ON period Tₒₙ, when the substrate 500 does not pass through the target overlapping region, sputtered particles are not deposited on the substrate 500. In other words, the effective ON period during which sputtered particles are deposited on the substrate 500 can be made shorter than the ON period Tₒₙ during which the AC voltage is applied to the target 130. Thus, the frequency of switching between the ON period Tₒₙ and the OFF period T_{off} can be reduced. Further, even during the ON period Tₒₙ, Ga on the surface of the substrate 500 can react with nitrogen in the gas containing nitrogen supplied to the vacuum chamber 100 in the target non-overlapping region of the substrate 500. Furthermore, since the time the substrate 500 is exposed to the plasma can be shortened, etching by N⁻ is not performed, and damage to the film formed on the substrate can be reduced. As a result, the gallium nitride film formed using the film formation apparatus 10 is a high-quality film. Moreover, since the load on the sputtering power supply unit 160 can be reduced, the frequency of maintenance of the sputtering power supply unit 160 can be reduced.

### Modification

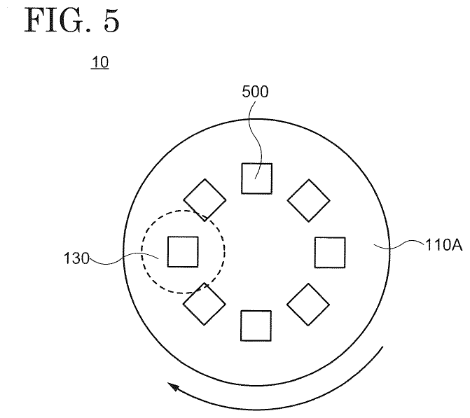

The configuration of the film formation apparatus 10 can be modified in various ways. Therefore, a modification of the substrate support portion 110 of the film formation apparatus 10 is described with reference to FIG. 5. In addition, a modification of the configuration of the film formation apparatus 10 is not limited thereto. In the following description, the description of the same configuration as that described above may be omitted.

FIG. 5 is a schematic diagram showing a configuration of a substrate support portion 110A of the film formation apparatus 10 according to an embodiment of the present invention.

As shown in FIG. 5, the substrate support portion 110A can support a plurality of substrates 500. The substrate support portion 110A preferably supports the plurality of substrates 500 so that the plurality of substrates 500 are arranged concentrically. Even in this case, a target overlapping region and a target non-overlapping region are spatially formed by the rotation of the plurality of substrates 500. Therefore, the substrates 500 periodically pass through the target overlapping region and the target non-overlapping region, thereby promoting a stepwise gallium nitride production reaction and forming a gallium nitride film with high quality. Further, by temporally controlling the sputtering power supply unit 160 and utilizing not only the ON period Tₒₙ but also the OFF period T_{off}, the stepwise gallium nitride production reaction can be promoted and a gallium nitride film with high quality can be formed.

As described above, according to the film formation apparatus 10 of the present embodiment, which includes the modification, the substrate 500 periodically passes through the target overlapping region where sputtering is performed and the target non-overlapping region where sputtering is not performed. Thus, a stepwise gallium nitride production reaction can be promoted. Therefore, a gallium nitride film with high quality can be formed on a sapphire substrate or a glass substrate at a low temperature (e.g., 400° C. to 650° C.). Further, when not only the ON period Tₒₙ but also the OFF period T_{off} is used, the on and off states of the sputtering power supply unit 160 are not frequently switched, thereby reducing the load on the sputtering power supply unit 160. Furthermore, highly corrosive gases such as ammonia gas are not required for gallium nitride film formation. Accordingly, when the film formation apparatus 10 is used, a gallium nitride film with high quality can be formed while reducing the energy required during film formation.

In addition, the film formation apparatus 10 can also form nitride films other than a gallium nitride film by using materials other than gallium nitride for the target 130.

### Second Embodiment

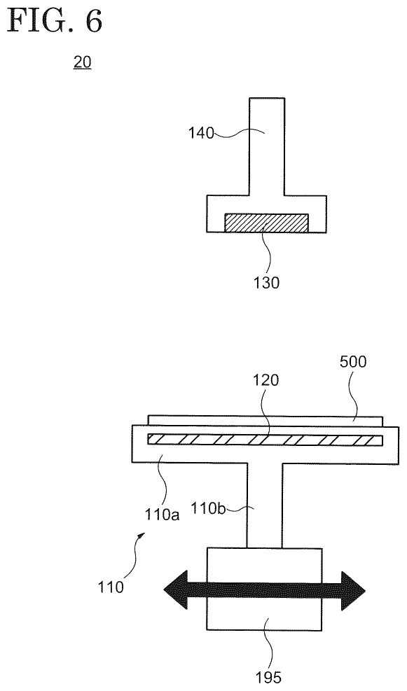

A film formation apparatus 20 according to an embodiment of the present invention is described with reference to FIG. 6. In the following description, when a configuration of the film formation apparatus 20 is similar to that of the film formation apparatus 10, the description of the configuration of the film formation apparatus 20 may be omitted.

FIG. 6 is a schematic diagram showing a part of a configuration of the film formation apparatus 20 according to an embodiment of the present invention.

As shown in FIG. 6, the film formation apparatus 20 includes the substrate support portion 110, the heating unit 120, the target 130, the target support portion 140, and a swing drive unit 195. The swing drive unit 195 may be a portion of the substrate support portion 110.

The substrate support portion 110 includes the flat plate member 110a and the support member 110b. One end of the support member 110b is connected to the flat plate member 110a, and the other end of the support member 110b is connected to the swing drive unit 195. The swing drive unit 195 can move the substrate support portion 110 back and forth in one direction. That is, the swing drive unit 195 can swing the substrate support portion 110 in one direction. As the substrate support portion 110 moves, the substrate 500 placed on the substrate support portion 110 also moves in one direction. In other words, the substrate support portion 110 supports the substrate 500 so that it can move in one direction.

In one direction in which the substrate moves, the length of the substrate 500 is greater than the length of the target 130. For example, the length of the substrate 500 is greater than or equal to four times the length of the target. On the other hand, in a direction perpendicular to the one direction (the depth direction of the paper in FIG. 6), the width of the substrate 500 is smaller than the width of the target 130. Therefore, the film formation apparatus 20 can form a gallium nitride film even on the substrate 500 that is larger than the target 130.

In the film formation apparatus 20, a portion of the substrate 500 overlaps the target 130 by oscillation of the substrate 500 in one direction periodically. In other words, a portion of the substrate 500 passes through the target overlapping region by oscillation of the substrate 500 in one direction. Also in the film formation apparatus 20, an AC voltage is also applied to the target 130, and the target overlapping region where sputtering is performed and the target non-overlapping region where sputtering is not performed are spatially formed within the vacuum chamber 100. In the film formation apparatus 20, sputtering is performed when a portion of the substrate 500 passes through the target overlapping region. Further, migration of Ga on the surface of the substrate 500 is promoted in the target non-overlapping region. Furthermore, since a gas containing nitrogen is supplied into the vacuum chamber 100, Ga on the surface of the substrate 500 reacts with nitrogen or a nitrogen radical with a long lifetime in the supplied gas, thereby forming a gallium nitride film on the substrate 500. Since etching with N⁻ is not performed and damage to the film formed on the substrate 500 can be reduced, the gallium nitride film formed using the film formation apparatus 20 is a high-quality film.

Further, in the film formation apparatus 20, the application of the AC voltage to the target 130 may be periodically stopped. In this case, sputtering in which the ON period Tₒₙ and the OFF period T_{off} for the portion passing through the target overlapping region is performed is repeated periodically. In the film formation apparatus 20, since the substrate 500 moves, the effective ON period during which sputtered particles are deposited on the substrate 500 can be made shorter than the ON period Tₒₙ during which the AC voltage is applied to the target 130. Furthermore, since the time during which the substrate 500 is exposed to plasma can be shortened, etching by N⁻ is not performed, and damage to the film formed on the substrate 500 can be reduced.

As described above, according to the film formation apparatus 20 of the present embodiment, a portion of the substrate 500 periodically passes through the target overlapping region where sputtering is performed and the target non-overlapping region where sputtering is not performed. Thus, a stepwise gallium nitride production reaction can be promoted. Therefore, a gallium nitride film with high quality can be formed on a sapphire substrate or a glass substrate at a low temperature (e.g., 400° C. to 650° C.). Further, when not only the ON period Tₒₙ but also the OFF period T_{off} is used, the on and off states of the sputtering power supply unit 160 are not frequently switched, thereby reducing the load on the sputtering power supply unit 160. Furthermore, highly corrosive gases such as ammonia gas are not required for gallium nitride film formation. Accordingly, when the film formation apparatus 20 is used, a gallium nitride film with high quality can be formed while reducing the energy required during film formation.

### Third Embodiment

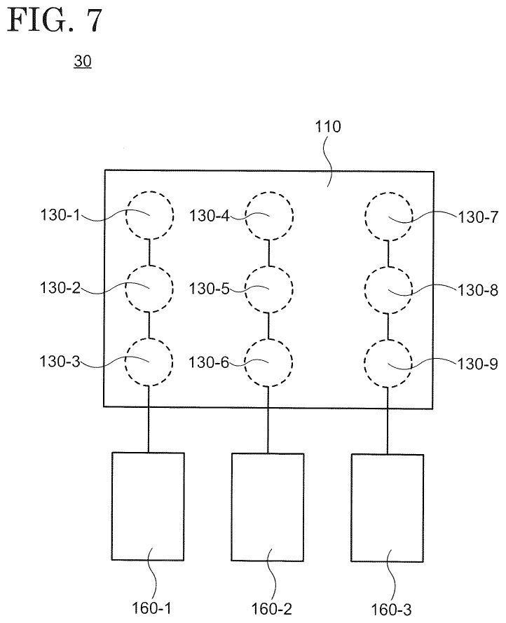

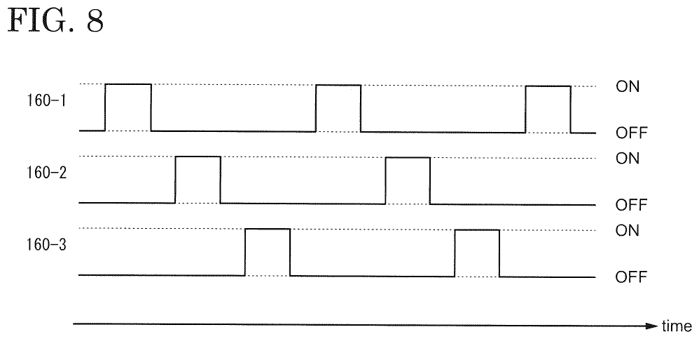

A film formation apparatus 30 according to an embodiment of the present invention is described with reference to FIGS. 7 and 8. In the following description, when a configuration of the film formation apparatus 30 is similar to that of the film formation apparatus 10, the description of the configuration of the film formation apparatus 30 may be omitted.

FIG. 7 is a schematic diagram showing a part of a configuration of the film formation apparatus 30 according to an embodiment of the present invention.

As shown in FIG. 7, the film formation apparatus 30 includes the substrate support portion 110, a first target 130-1 to a ninth target 130-9, and a first sputtering power supply unit 160-1 to a third sputtering power supply unit 160-3.

The first sputtering power supply unit 160-1 is connected to the first target 130-1 to the third target 130-3 and can simultaneously apply an AC voltage to the first target 130-1 to the third target 130-3. The second sputtering power supply unit 160-2 is connected to the fourth target 130-4 to the sixth target 130-6 and can simultaneously apply an AC voltage to the fourth target 130-4 to the sixth target 130-6. The third sputtering power supply unit 160-3 is connected to the seventh target 130-7 to the ninth target 130-9 and can simultaneously apply an AC voltage to the seventh target 130-7 to the ninth target 130-9. The first sputtering power supply unit 160-1 to the third sputtering power supply unit 160-3 can each generate an AC voltage independently.

Although FIG. 7 shows nine targets 130, the number of targets 130 is not limited to nine. In the film formation apparatus 30, the plurality of targets 130 can be arranged according to the size of the substrate 500. Therefore, a gallium nitride film can be formed on the substrate 500 larger than one target 130 in the film formation apparatus 30. Further, although FIG. 7 shows three sputtering power supply units 160, an AC voltage may be applied to the partitioned targets 130 by switching one sputtering power supply unit 160 with a switch.

FIG. 8 is a sequence diagram of the first sputtering power supply unit 160-1 to the third sputtering power supply unit 160-3 controlled by the control unit 200 of the film formation apparatus 30 according to an embodiment of the present invention.

As shown in FIG. 8, the control unit 200 controls each of the first sputtering power supply unit 160-1 to the third sputtering power supply unit 160-3 so that the ON period Tₒₙ and the OFF period T_{off} are periodically repeated. The ON period Tₒₙ is less than or equal to 25% of the total period of the ON period Tₒₙ and the OFF period T_{off}. It is preferable that the ON periods Tₒₙ of the first sputtering power supply unit 160-1 to the third sputtering power supply unit 160-3 do not overlap each other. In the film formation apparatus 30, the substrate support portion 110 is not moved. Sputtering is performed on a portion of the substrate 500 included in the target overlapping region by only temporally controlling the ON period Tₒₙ and the OFF period T_{off} in the region overlapping with the target 130. In the film formation apparatus 30, the effective ON period during which sputtered particles are deposited on the substrate 500 is the same as the ON period Tₒₙ of the sputtering power supply unit 160. Therefore, although the load on the sputtering power supply unit 160 cannot be reduced, the generation of particles inside the vacuum chamber 100 can be suppressed because the substrate support portion 110 is not moved.

As described above, according to the film formation apparatus 30 of the present embodiment, the ON period Tₒₙ during which sputtering is performed and the OFF period T_{off} during which sputtering is not performed are used without moving the substrate 500. Thus, a gallium nitride film with high quality can be formed on a sapphire substrate or a glass substrate at a low temperature (e.g., 400° C. to 650° C.). In the film formation apparatus 30, since the substrate support portion 110 is not moved, the generation of particles in the vacuum chamber 100 can be suppressed. Further, highly corrosive gases such as ammonia gas are not required for gallium nitride film formation. Accordingly, when the film formation apparatus 30 is used, a gallium nitride film with high quality can be formed while reducing the energy required during film formation.

### Fourth Embodiment

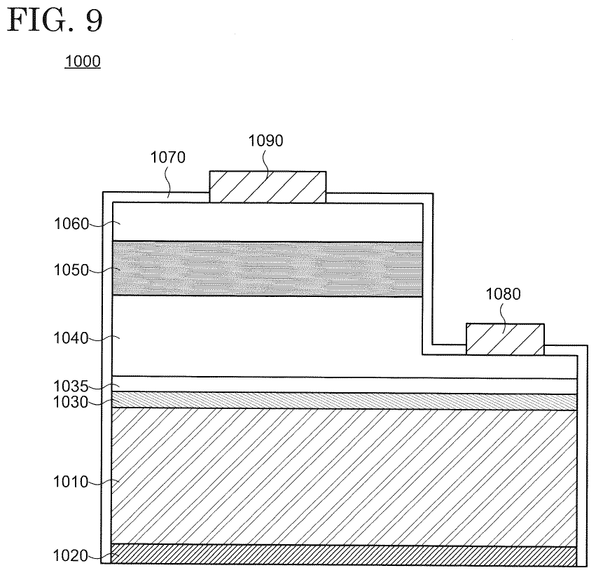

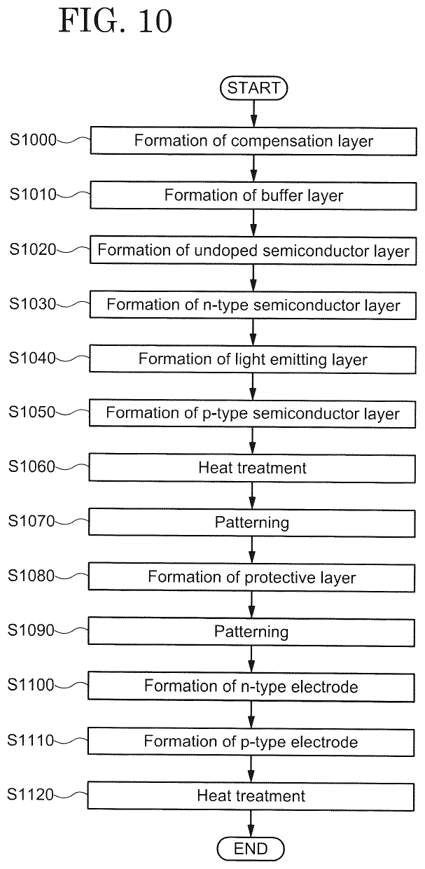

A light emitting element 1000 according to an embodiment of the present invention is described with reference to FIGS. 9 and 10.

### 1. Configuration of Light Emitting Element 1000

FIG. 9 is a schematic diagram showing a configuration of a light emitting element 1000 according to an embodiment of the present invention.

As shown in FIG. 9, the light emitting element 1000 includes a substrate 1010, a compensation layer 1020, a buffer layer 1030, an undoped semiconductor layer 1035, an n-type semiconductor layer 1040, a light emitting layer 1050, a p-type semiconductor layer 1060, a protective layer 1070, an n-type electrode 1080, and a p-type electrode 1090. Although the light emitting element 1000 is a so-called LED (Light Emitting Diode), the light emitting element 1000 is not limited thereto.

For example, a glass substrate or a quartz substrate can be used as the substrate 1010. When the film formation apparatus 10 is used, a gallium nitride film can be formed at a low temperature. Therefore, an inexpensive glass substrate can be used as the substrate 1010.

The glass substrate is an amorphous substrate containing a glass material that does not generally have a crystalline structure but has a crystalline structure in a fine region. The upper limit of the thermal expansion coefficient of the glass substrate is less than 4.2×10⁻⁶/K, and preferably less than 4.0×10⁻⁶/ K. The lower limit of the thermal expansion coefficient of the glass substrate is greater than 3.0×10⁻⁶/K, and preferably greater than 3.5×10⁻⁶/K. The glass substrate requires resistance to the thermal history during the manufacture of a semiconductor device. Therefore, the lower limit of the glass transition point of the glass substrate is, for example, greater than or equal to 650° C., and preferably greater than or equal to 720° C. Further, the upper limit of the glass transition point of the glass substrate is, for example, less than or equal to 900° C., and preferably less than or equal to 810° C. For the same reason, the lower limit of the softening point of the glass substrate is, for example, greater than or equal to 900° C., and preferably greater than or equal to 950° C. The upper limit of the softening point of the glass substrate is, for example, less than or equal to 1150° C., and preferably less than or equal to 1050° C.

A glass material with a low content of alkali metal components can be used for the glass substrate in order to prevent the alkali metal components in the glass material from contaminating the light emitting layer 1050. For example, the content of the alkali metals in the glass substrate is less than or equal to 0.1% by mass.

For example, an amorphous containing glass material aluminoborosilicate glass or aluminosilicate glass is used for such an amorphous glass substrate. Such an amorphous glass material is used in a liquid crystal display or an organic electroluminescent (organic EL) display, and a large-area glass substrate called a mother glass is provided on the market. When a glass substrate is selected as the substrate of the light emitting element 1000, the light emitting element 1000 can be manufactured at low cost.

The substrate 1010 has a first surface on which the light emitting layer 1050 is formed, and a second surface on which the compensation layer 1020 is formed. The surface roughness of the first surface and the second surface of the substrate 1010 do not need to be the same. However, from the viewpoint of preventing electrostatic damage due to a peeling charge when the light emitting element 1000 is removed from various apparatuses during the manufacturing process of the light emitting element 1000, the surface roughness of the second surface can be made rougher than the surface roughness of the first surface.

Although the thickness of the substrate 1010 is not particularly limited to a specific thickness, a substrate that is sufficiently thicker than the total thickness of the n-type semiconductor layer 1040, the light emitting layer 1050, and the p-type semiconductor layer 1060 can be used from the viewpoint of reducing warpage of the substrate 1010. For example, the substrate 1010 has a film thickness greater than or equal to 50 times the total film thickness of the n-type semiconductor layer 1040, the light emitting layer 1050, and the p-type semiconductor layer 1060. The substrate 1010 has a thickness of, for example, 0.5 to 1.0 mm.

Although the mechanical strength of the substrate 1010 is not particularly limited to a specific value, it is preferable that the substrate 1010 has a Young's modulus of, for example, 70 to 90 GPa from the viewpoint of reducing warpage of the substrate 1010.

The compensation layer 1020 is formed on the second surface of the substrate 1010. When the compensation layer 1020 is provided on the second surface, warpage of the substrate 1010, which is disadvantageous when the light emitting element 1000 is manufactured, can be reduced. Further, when the compensation layer 1020 is provided on the second surface, degassing such as H₂O from the second surface side of the substrate 1010 can be reduced during decompression and heating for forming the n-type semiconductor layer 1040, the light emitting layer 1050, and the p-type semiconductor layer 1060, and the intrusion of oxygen into the n-type semiconductor layer 1040, the light emitting layer 1050, and the p-type semiconductor layer 1060 can be reduced. Furthermore, by appropriately selecting the material of the compensation layer 1020, the resistance to the chemical treatment with acid used in the manufacturing process of the light emitting element 1000 is also improved.

The compensation layer 1020 can reduce warpage of the substrate 1010 caused by the difference in thermal expansion coefficient between the substrate 1010 and the n-type semiconductor layer 1040, the light emitting layer 1050, or the p-type semiconductor layer 1060 by setting the thermal expansion coefficient within a predetermined range. The thermal expansion coefficient of the compensation layer 1020 is greater than that of the substrate 1010 and is less than that of the substrate 1010 and the n-type semiconductor layer 1040, the light emitting layer 1050, and the p-type semiconductor layer 1060. The lower limit of the thermal expansion coefficient of the compensation layer 1020 is, for example, greater than 4.0×10⁻⁶/K, and preferably greater than 4.1×10⁻⁶/K. The upper limit of the thermal expansion coefficient of the compensation layer 1020 is, for example, less than 5.0×10⁻⁶/K, and preferably less than 4.6×10⁻⁶/K.

Since the compensation layer 1020 is adjacent to the substrate 1010, heat can be efficiently and uniformly transferred to the entire substrate 1010 in the heating process for forming the n-type semiconductor layer 1040, the light emitting layer 1050, and the p-type semiconductor layer 1060 on the substrate 1010 by setting the thermal conductivity to a predetermined value. As a result, the uniformity of the thicknesses of the n-type semiconductor layer 1040, the light emitting layer 1050, and the p-type semiconductor layer 1060 can be improved. Therefore, the compensation layer 1020 can have a thermal conductivity that exceeds the thermal conductivity of the substrate 1010. The thermal conductivity of the compensation layer 1020 can be appropriately set depending on the material of the substrate 1010, and is, for example, greater than 10 Wm⁻¹K⁻¹, and preferably greater than 40 Wm⁻¹K⁻¹.

The thermal conductivity of the compensation layer 1020 can be adjusted by adjusting the film density to a predetermined value. Although the relationship between the film density and the thermal conductivity varies depending on the material of the compensation layer 1020, the lower limit of the film density of the compensation layer 1020 is, for example, greater than or equal to 2.50 g/cm³, and preferably greater than or equal to 2.60 g/cm³. The upper limit of the film density of the compensation layer 1020 is less than or equal to 4.10 g/cm³, and preferably less than or equal to 4.00 g/cm³.

Although the material used for the compensation layer 1020 is not particularly limited to a certain material as long as it satisfies the above-described physical property values, it is preferable that the material is resistant to a chemical treatment with acid or the like used in the manufacturing process of the light emitting element 1000. For example, an aluminum nitride film or an aluminum oxide film, or a stacked film of an aluminum nitride film and an aluminum oxide film can be used as the compensation layer 1020.

The method for forming the compensation layer 1020 is not limited to a certain method and any known film formation method can be used. However, it is preferable to form the compensation layer 1020 using sputtering in order to form the compensation layer 1020 on a large-area substrate and to prevent the temperature of the substrate 1010 from excessively increasing during the formation of the compensation layer 1020. The sputtering conditions are not limited to certain conditions, and a known sputtering apparatus can be used and the conditions can be set appropriately.

The thickness of the compensation layer 1020 is not particularly limited to a certain thickness, and is set appropriately depending on the structure of the light emitting element 1000. However, the compensation layer 1020 can be formed so as not to be excessively thin compared to the total thickness of the n-type semiconductor layer 1040, the light emitting layer 1050, and the p-type semiconductor layer 1060 from the viewpoint of reducing warpage of the substrate 1010. For example, the compensation layer 1020 can have a thickness greater than or equal to 80% of the total thickness of the n-type semiconductor layer 1040, the light emitting layer 1050, and the p-type semiconductor layer 1060.

The buffer layer 1030 can control the crystal orientation of the undoped semiconductor layer 1035 and the n-type semiconductor layer 1040, and can improve the crystallinity of the n-type semiconductor layer 1040. For example, an aluminum nitride film or the like can be used as the buffer layer 1030.

The undoped semiconductor layer 1035 can promote epitaxial growth of the n-type semiconductor layer 1040. For example, a gallium nitride film or the like can be used as the undoped semiconductor layer 1035.

A gallium nitride film doped with silicon can be used as the n-type semiconductor layer 1040. A stacked structure in which an indium gallium nitride film and a gallium nitride film are alternately stacked can be used for the light emitting layer 1050. A gallium nitride film doped with magnesium can be used as the p-type semiconductor layer 1060. A silicon oxide film can be used as the protective layer 1070. A metal film such as indium can be used for the n-type electrode 1080. A metal film such as palladium or gold can be used for the p-type electrode 1090. In addition, it is preferable that the oxygen concentration in the light emitting layer 1050 and the p-type semiconductor layer 1060 is less than 1×10¹⁸ cm⁻³.

### 2. Method for Manufacturing Light Emitting Element 1000

FIG. 10 is a flow chart showing a method for manufacturing the light emitting element 1000 according to an embodiment of the present invention.

In step S1000, an aluminum nitride film is formed on the second surface of the substrate 1010 as the compensation layer 1020. The aluminum nitride film can be formed using the film formation apparatus 10 or another sputtering apparatus. When the deposition apparatus 10 is used, aluminum or aluminum nitride is used as the target 130.

In step S1010, an aluminum nitride film is formed on the first surface of the substrate 1010 as the buffer layer 1030. The aluminum nitride film can be formed using the film formation apparatus 10 or another sputtering apparatus. When the film formation apparatus 10 is used, aluminum or aluminum nitride is used as the target 130.

In step S1020, a gallium nitride film is formed on the buffer layer 1030 as the undoped semiconductor layer 1035. The gallium nitride film can be formed using the film formation apparatus 10.

In step S1030, a gallium nitride film doped with silicon is formed on the undoped semiconductor layer 1035 as the n-type semiconductor layer 1040. The gallium nitride film doped with silicon can be formed using the film formation apparatus 10. Specifically, gallium nitride doped with silicon is used as the target 130.

In step S1040, indium gallium nitride films and gallium nitride films are alternately formed on the n-type semiconductor layer 1040 as the light emitting layer 1050. The indium gallium nitride film and the gallium nitride film can be formed using the film formation apparatus 10. In the formation of the indium gallium nitride film, indium gallium nitride is used as target 130.

In step S1050, a gallium nitride film doped with magnesium is formed on the light emitting layer 1050 as the p-type semiconductor layer 1060. The gallium nitride film doped with magnesium can be formed using the film formation apparatus 10. Specifically, gallium nitride doped with magnesium is used as the target 130.

In step S1060, a heat treatment is performed. The activation rate of the magnesium added into the gallium nitride film in step S1050 may be low. In this case, the magnesium can be activated by performing a heat treatment to allow the layer to function as the p-type semiconductor layer 1060.

In step S1070, the p-type semiconductor layer 1060, the light emitting layer 1050, and the n-type semiconductor layer 1040 are etched into a predetermined pattern using photolithography. In addition, the n-type semiconductor layer 1040 is etched so that its surface is exposed (i.e., so that a part of the n-type semiconductor layer 1040 remains). For example, plasma etching can be used as the etching.

In step S1080, a silicon oxide film is formed as a protective layer 1070 so as to cover the surface of the p-type semiconductor layer 1060, the exposed surface of the n-type semiconductor layer 1040, and the side surfaces of each layer. The silicon oxide film can be formed using a CVD apparatus.

In step S1090, the protective layer 1070 is patterned using photolithography so as to form openings that expose the surfaces of the p-type semiconductor layer 1060 and the n-type semiconductor layer 1040.

In step S1100, a metal stacked film of Ti/Al/Ti/Au is formed on the n-type semiconductor layer 1040 through the opening as the n-type electrode 1080.

In step S1110, a metal stacked film of Ni/Au is formed on the p-type semiconductor layer 1060 through the opening as the p-type electrode 1090.

In step S1120, a heat treatment is performed. In this way, the contact resistance between the n-type semiconductor layer 1040 and the n-type electrode 1080 and the contact resistance between the p-type semiconductor layer 1060 and the p-type electrode 1090 can be reduced.

As described above, the light emitting element 1000 of the present embodiment can include a gallium nitride film with high quality when the film formation apparatus 10 is used. Further, since a gallium nitride film is formed at a low temperature without using highly corrosive gasses, the energy required during film formation can be reduced.

### Fifth Embodiment

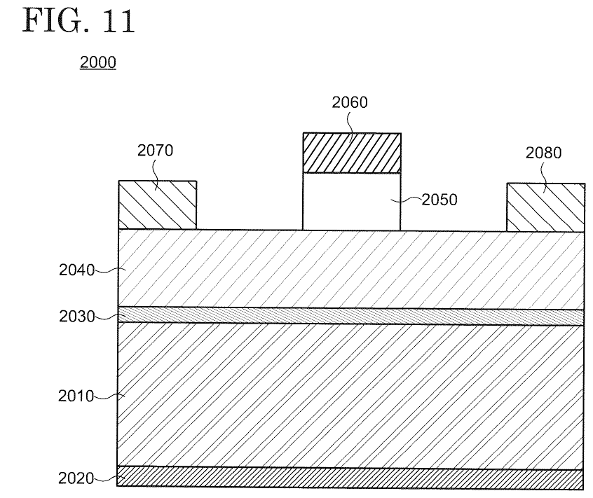

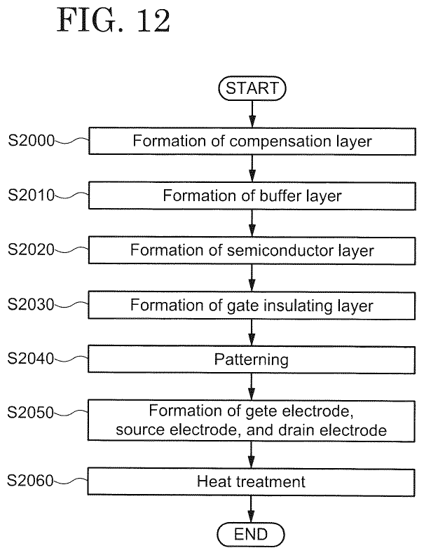

A semiconductor element 2000 according to an embodiment of the present invention is described with reference to FIGS. 11 and 12.

### 1. Configuration of Semiconductor Element 2000

FIG. 11 is a schematic diagram showing a configuration of the semiconductor element 2000 according to an embodiment of the present invention.

As shown in FIG. 11, the semiconductor element 2000 includes a substrate 2010, a compensation layer 2020, a buffer layer 2030, a semiconductor layer 2040, a gate insulating layer 2050, a gate electrode 2060, a source electrode 2070, and a drain electrode 2080. Although the semiconductor element 2000 is a so-called transistor, the semiconductor element 2000 is not limited thereto.

Since the substrate 2010, the compensation layer 2020, and the buffer layer 2030 are similar to the substrate 1010, the compensation layer 1020, and the buffer layer 1030 of the Third Embodiment, respectively, the description thereof is omitted here.

For example, a gallium nitride film doped with silicon (n-type gallium nitride semiconductor film) or a gallium nitride film (undoped gallium nitride semiconductor film) can be used as the semiconductor layer 2040. A silicon oxide film or a silicon nitride film can be used as the gate insulating layer 2050. A metal film such as aluminum (Al), nickel (Ni), titanium (Ti), gold (Au), silver (Ag), palladium (Pd), and indium (In) or a stacked metal film thereof can be used for each of the gate electrode 2060, the source electrode 2070, and the drain electrode 2080.

### 2. Method for Manufacturing Semiconductor Element 2000

FIG. 12 is a flow chart illustrating a method for manufacturing the semiconductor element 2000 according to an embodiment of the present invention.

In step S2000, an aluminum nitride film is formed as the compensation layer 2020 on the second surface of the substrate 2010. The aluminum nitride film can be formed using the film formation apparatus 10 or another sputtering apparatus. When the film formation apparatus 10 is used, aluminum or aluminum nitride is used as the target 130.

In step S2010, an aluminum nitride film is formed as the buffer layer 2030 on the first surface of the substrate 2010. The aluminum nitride film can be formed using the film formation apparatus 10 or another sputtering apparatus. When the film forming apparatus 10 is used, aluminum or aluminum nitride is used as the target 130.

In step S2020, a gallium nitride film is formed as the semiconductor layer 2040 on the buffer layer 2030. The gallium nitride film can be formed using the film formation apparatus 10.

In step S2030, a silicon oxide film is formed as the gate insulating layer 2050 on the semiconductor layer 2040. The silicon oxide film can be formed using a CVD apparatus.

In step S2040, the gate insulating layer 2050 and the semiconductor layer 2040 are patterned using photolithography. The gate insulating layer 2050 is patterned so as to expose the surface of the semiconductor layer 2040. The semiconductor layer 2040 is patterned in an island shape.

In step S2050, a stacked metal film of Ti/Al is formed as the gate electrode 2060 on the gate insulating layer 2050. Further, the stacked metal film of Ti/Al is formed as the source electrode 2070 and the drain electrode 2080 on the exposed surface of the semiconductor layer 2040.

In step S2060, a heat treatment is performed. In this way, the contact resistance between the semiconductor layer 2040 and the source electrode 2070, and the contact resistance between the semiconductor layer 2040 and the drain electrode 2080 can be reduced.

As described above, the semiconductor element 2000 of the present embodiment can include a gallium nitride film with high quality when the film formation apparatus 10 is used. Further, since a gallium nitride film is formed at a low temperature without using highly corrosive gasses, the energy required during film formation can be reduced.

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A film formation apparatus, comprising:
a vacuum chamber capable of evacuating an interior thereof;
a substrate support portion provided in the vacuum chamber and configured to support at least one substrate;
a target support portion provided in the vacuum chamber and configured to support a target containing nitrogen and gallium;
a sputtering gas supply unit connected to the vacuum chamber and configured to supply a sputtering gas to the vacuum chamber;
a nitrogen gas supply unit connected to the vacuum chamber and configured to supply a gas containing nitrogen to the vacuum chamber; and
a sputtering power supply unit configured to apply an AC voltage to the target,
wherein the substrate support portion supports the at least one substrate such that the at least one substrate periodically passes through a region overlapping the target.

2. The film formation apparatus according to claim 1, wherein the substrate support portion rotatably supports the at least one substrate.

3. The film formation apparatus according to claim 1, wherein the substrate support portion supports the at least one substrate so as to be movable along one direction.

4. The film formation apparatus according to claim 1, further comprising a control unit configured to control the sputtering power supply unit,
wherein the control unit periodically controls an ON period during which the AC voltage is applied to the target and an OFF period during which the AC voltage is not applied to the target.

5. The film formation apparatus according to claim 4, wherein the control unit controls the ON period and the OFF period so that the ON period is less than or equal to 25% of a total period of the ON period and the OFF period.

6. A film formation apparatus, comprising:
a vacuum chamber capable of evacuating an interior thereof;
a substrate support portion provided in the vacuum chamber and configured to support at least one substrate;
a first target support portion provided in the vacuum chamber and configured to support a first target;
a second target support portion provided in the vacuum chamber and configured to support a second target;
a sputtering gas supply unit connected to the vacuum chamber and configured to supply a sputtering gas to the vacuum chamber;
a nitrogen gas supply unit connected to the vacuum chamber and configured to supply a gas containing nitrogen to the vacuum chamber;
a first sputtering power supply unit configured to apply a first AC voltage to the first target;
a second sputtering power supply unit configured to apply a second AC voltage to the second target; and
a control unit configured to control the first sputtering power supply unit and the second sputtering power supply unit,
wherein each of the first target and the second target contains nitrogen and gallium, and
wherein the control unit periodically controls a first ON period during which the first AC voltage is applied to the first target and a first OFF period during which the first AC voltage is not applied to the first target, and a second ON period during which the second AC voltage is applied to the second target and a second OFF period during which the second AC voltage is not applied to the second target.

7. The film formation apparatus according to claim 6,
wherein the control unit controls the first sputtering power supply unit so that the first ON period is less than or equal to 25% of a total period of the first ON period and the first OFF period, and
wherein the control unit controls the second sputtering power supply unit so that the second ON period is less than or equal to 25% of a total period of the second ON period and the second OFF period.

8. The film formation apparatus according to claim 7, wherein the control unit controls the first sputtering power supply unit and the second sputtering power supply unit so that the first ON period and the second ON period do not overlap each other.

9. A film formation method of a gallium nitride film, comprising the steps of:
placing a substrate so as to face a target containing nitrogen and gallium in a vacuum chamber;
heating the substrate;
moving the substrate so that at least a portion of the substrate periodically passes through a region overlapping the target;
supplying a gas containing nitrogen to the vacuum chamber; and
applying an AC voltage to the target.

10. The film formation method of a gallium nitride film according to claim 9,
wherein the AC voltage comprises a first period during which the AC voltage is applied to the target and a second period during which the application of the AC voltage to the target is stopped after the first period, and
wherein the first period and the second period are repeated periodically.

11. The film formation method of a gallium nitride film according to claim 9, wherein the first period and the second period are repeated periodically such that the first period is less than or equal to 25% of a total period of the first period and the second period.

12. The film formation method of a gallium nitride film according to claim 10, wherein the gas containing nitrogen is supplied during the second period.

13. The film formation method of a gallium nitride film according to claim 9, wherein the gas further contains hydrogen.

14. The film formation method of a gallium nitride film according to claim 9,
wherein the substrate is a sapphire substrate, and
wherein the sapphire substrate is heated at a temperature higher than or equal to 400° C. and lower than or equal to 650° C.

15. The film formation method of a gallium nitride film according to claim 9,
wherein the substrate is a glass substrate, and
wherein the glass substrate is heated at a temperature higher than or equal to 400°° C. and lower than or equal to 650° C.
